(19) United States
(12) Patent Application Publication
(10) Pub. No.: US 2026/0150246 A1
(43) Pub. Date: May 28, 2026

(54) Refrigerant Loop Heat Sink

(71) Applicant: Rheem Manufacturing Company, Atlanta, GA (US)

(72) Inventors: Michael John Knieser, Fishers, IN (US); Veera Malayappan, Montgomery, AL (US); Mehdi Famouri, Atlanta, GA (US); Chris Allen Baker, Pike Road, AL (US); Cameron Joseph Wright, Indianapolis, IN (US); Gregory A. Lyon, Fortville, IN (US)

(21) Appl. No.: 19/400,454

(22) Filed: Nov. 25, 2025

Related U.S. Application Data
(60) Provisional application No. 63/725,313, filed on Nov. 26, 2024.

(51) Int. Cl. H05K 7/20

(52) U.S. Cl. CPC H05K 7/2039

(57) ABSTRACT

Described herein is a refrigerant loop heat sink. The heat sink may be provided in contact with refrigerant tubing that is connected to an existing refrigerant loop of the heating and/or cooling appliance. The heat sink may then be provided in thermal contact with electronic components (or a printed circuit board (PCB) to which the electronic components are mounted) of the heating and/or cooling appliance). In this manner, any heat that is produced as a byproduct of the operation of the electronic components may be transferred from the electronic components into the heat sink and the refrigerant tubing. The heat may then be transferred to the refrigerant that is flowing through the refrigerant tubing to cool the electronic components. This provides an alternative to an air cooled system by which heat from the electronic components is dissipated by blowing cooler air from a fan within the heating and/or cooling appliance over the electronic components.

### CROSS REFERENCE TO RELATED APPLICATION

This application claims the benefit of U.S. Application No. 63/725,313, filed Nov. 26, 2024, the entirety of which is hereby incorporated by reference.

### TECHNICAL FIELD

The present disclosure is generally in the field of heating and/or cooling appliances.

### BACKGROUND

Temperature is a major factor in the reliability of variable speed drives (VFDs) and other types of electronic components in general. In some instances, electronic components may be constantly operational while a system (such as a heating and/or cooling appliance) is operational, resulting in the electronic components experiencing high temperatures as a byproduct of their operation. These high temperatures can degrade performance, shorten service life, and cause overheating, often resulting in the failure of such electronic components. In fact, 80-90% of VFD failures are due to excessive temperatures or unsuitable environments.

### BRIEF DESCRIPTION OF THE DRAWINGS

FIG. 1 depicts an exemplary heating and/or cooling appliance, in accordance with one or more embodiments of the disclosure.

FIGS. 2A-2C depict various refrigerant loops including a controller, in accordance with one or more embodiments of the disclosure.

FIG. 3 depicts an exemplary heat sink for a refrigerant loop and an electronics mounting plate that receives the heat sink, in accordance with one or more embodiments of the disclosure.

FIGS. 4-6 depict additional exemplary heat sinks for a refrigerant loop, in accordance with one or more embodiments of the disclosure.

FIGS. 7-8 depict additional exemplary heat sinks without refrigerant tubing, in accordance with one or more embodiments of the disclosure.

FIG. 9 depicts another electronics mounting plate that receives a heat sink, in accordance with one or more embodiments of the disclosure.

FIGS. 10-11 depict cross-section views of additional heat sinks with refrigerant tubing, in accordance with one or more embodiments of the disclosure.

FIG. 12A depicts a perspective view of another heat sink without refrigerant tubing, in accordance with one or more embodiments of the disclosure.

FIG. 12B depicts a cross-section view of the heat sink of FIG. 12A including refrigerant tubing, in accordance with one or more embodiments of the disclosure.

FIG. 13A depicts a perspective view of another heat sink, in accordance with one or more embodiments of the disclosure.

FIG. 13B depicts a cross-section view of the heat sink of FIG. 13A including refrigerant tubing, in accordance with one or more embodiments of the disclosure.

FIGS. 14A-14B depict cross-section views of different types of refrigerant tubing, in accordance with one or more embodiments of the disclosure.

FIG. 15 depicts a top-down view of a portion of refrigerant tubing, in accordance with one or more embodiments of the disclosure.

FIG. 16 depicts a cross-section view of the refrigerant tubing of FIG. 15, in accordance with one or more embodiments of the disclosure.

FIG. 17 depicts an exemplary heat sink for a refrigerant loop mounted on an electronics mounting plate, in accordance with one or more embodiments of the disclosure.

FIG. 18 depicts an exemplary heat sink for a refrigerant loop mounted on an electronics mounting plate, in accordance with one or more embodiments of the disclosure.

FIG. 19A depicts an exploded view of components for mounting a heat sink to a printed circuit board, in accordance with one or more embodiments of the disclosure.

FIG. 19B-19D depict an exemplary installation process for a printed circuit board and a heat sink, in accordance with one or more embodiments of the disclosure.

FIG. 19E-19F depict a heat sink mounted to a printed circuit board, in accordance with one or more embodiments of the disclosure.

### DETAILED DESCRIPTION

The present disclosure is directed to a refrigerant loop heat sink (also generally referred to as a “heat sink” herein). Particularly, the refrigerant loop heat sink provides a thermal interface for heat dissipation from electrical components included on and/or within the heating and/or cooling appliance to refrigerant that is flowing through refrigerant tubing of an existing refrigerant loop of the heating and/or cooling appliance. A heating and/or cooling appliance may generally refer to any system configured to heat and/or cool the air in a conditioned space, such as a heating, ventilation, and air conditioning (HVAC) system. Non-limiting examples of such systems may include heat pumps, gas furnaces, air conditioning systems, etc. However, a heating and/or cooling appliance may not necessarily be limited to heating and/or cooling air. As another example, a heating and/or cooling appliance may generally refer to any system configured to produce a heated fluid, such as a water heater, a boiler, a pool heater, etc. A heating and/or cooling appliance may also be used to heat and/or cool any other fluid, such as a gas, liquid, etc. Yet further examples of heating and/or cooling appliances may include integrated heat pump water heaters (HPWHs), monobloc/split HPWHs, Packaged HVAC units, split HVAC units, etc.

As one non-limiting example, the refrigerant loop heat sink may leverage refrigerant from the refrigerant loop of a heat pump system to cool electronic components of a VFD board of the heat pump. However, reference to a heat pump is merely exemplary and the approach described herein may also be applicable to other types of heating and/or cooling systems that include electronic components that may experience high operational temperatures and a refrigerant loop that may be leveraged to cool the electronic components. The refrigerant loop heat sink may be used in both residential and commercial applications.

Placement of the heat sink loop in the refrigerant circuit may provide a number of advantages (for example, the liquid loop has more thermal capacity, two-phase fluid leverages latent heat of vaporization for heat transfer, etc.). The relative temperature of the refrigerant flowing through the refrigerant loop may be lower than the operating temperature of any electronics that are cooled using the refrigerant loop heat sink as described herein. Therefore, the refrigerant from the refrigerant loop provides an effective mechanism for thermal transfer from the electronics to the refrigerant to dissipate heat from the electronics.

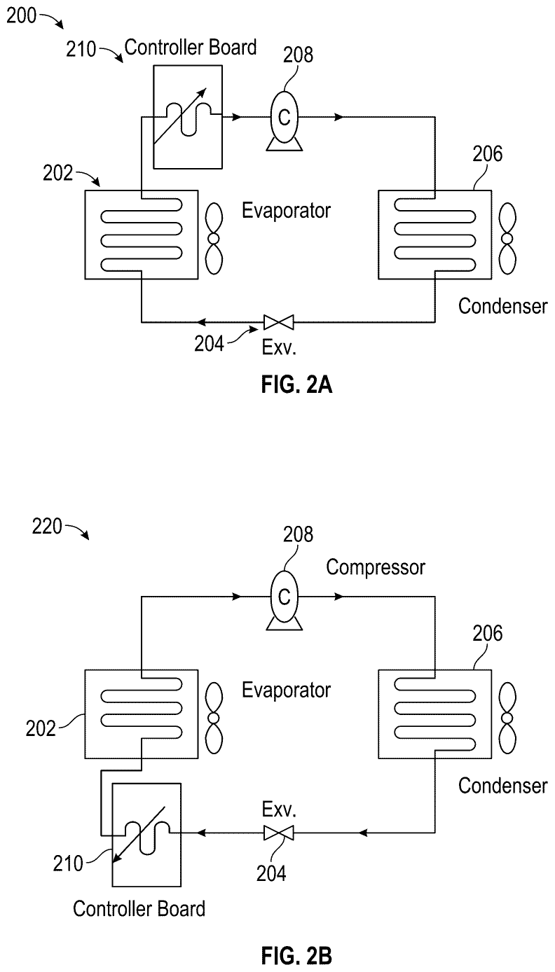

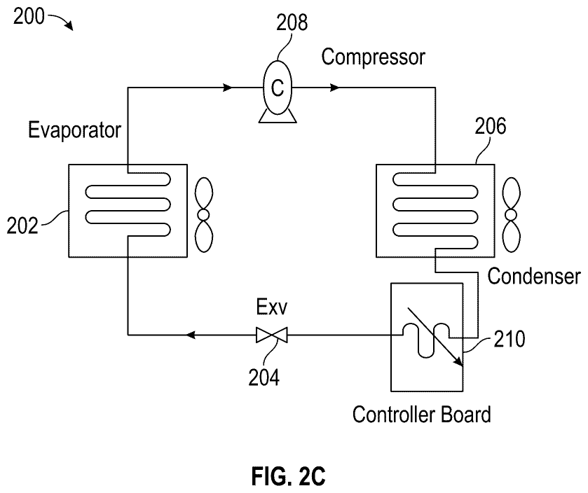

The refrigerant loop heat sink may be inserted into different locations within the refrigerant loop of the system. As one example, the refrigerant loop heat sink may be a suction gas cooler whereby the gaseous refrigerant in the refrigerant loop is used as a cooling medium to cool the electronic components. As a second example, the refrigerant loop heat sink may be a flash refrigerant cooler, where the rapidly evaporating refrigerant downstream of the expansion valve is used as a cooling medium to cool the electronic components. As a third example, the refrigerant loop heat sink may be a liquid loop cooler, where the subcooled refrigerant downstream of the condenser is used as a cooling medium to cool the electronic components. These are merely a few exemplary configurations and other configurations may also be possible. Diagrams illustrating potential locations of the refrigerant loop heat sink within the conventional refrigerant loop of a system are shown in FIGS. 2A-2C and are described in further detail below.

In some embodiments, the heat sink may include a block that is made from a material that allows for effective thermal transfer. For example, the block may be made from an aluminum or copper material, however, other types of materials are also possible. The block may be configured to interface with (e.g., be placed in contact with) refrigerant tubing associated with the existing refrigerant loop of the heating and/or cooling appliance. For example, existing refrigerant tubing may be re-routed to the heat sink or additional refrigerant tubing may be added to the existing refrigerant tubing and this additional refrigerant tubing may be routed to the heat sink. In this manner, the refrigerant may flow through both the existing refrigerant loop as well as the portion of the refrigerant loop that is provided in contact with the heat sink. In some configurations, the heat sink may include a plate or other type of structure instead of a “block” (or any other interface that allows for thermal transfer from the electronic components to the refrigerant tubing).

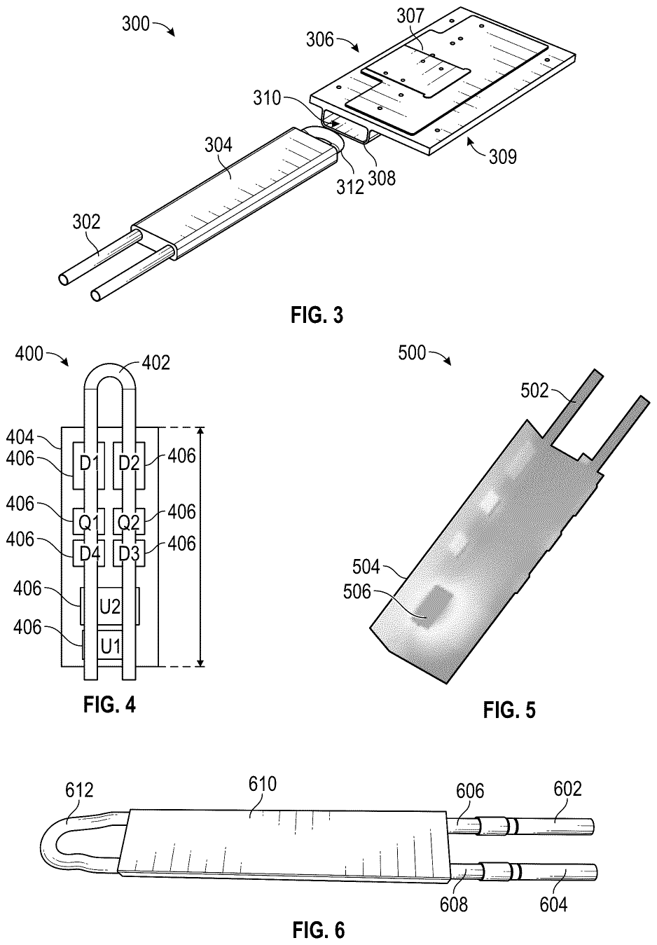

In either case, the refrigerant tubing may be in contact with the heat sink such that thermal transfer may occur between the heat sink and the refrigerant tubing (and the fluid flowing through the refrigerant tubing). In some embodiments (for example, shown in FIG. 3), the refrigerant tubing may be routed through the block of the heating sink. In other embodiments, the refrigerant tubing may be in contact with the block such that fluid may flow from the refrigerant tubing into the block, but the refrigerant tubing itself may not necessarily route through the block (for example, as shown in FIG. 4).

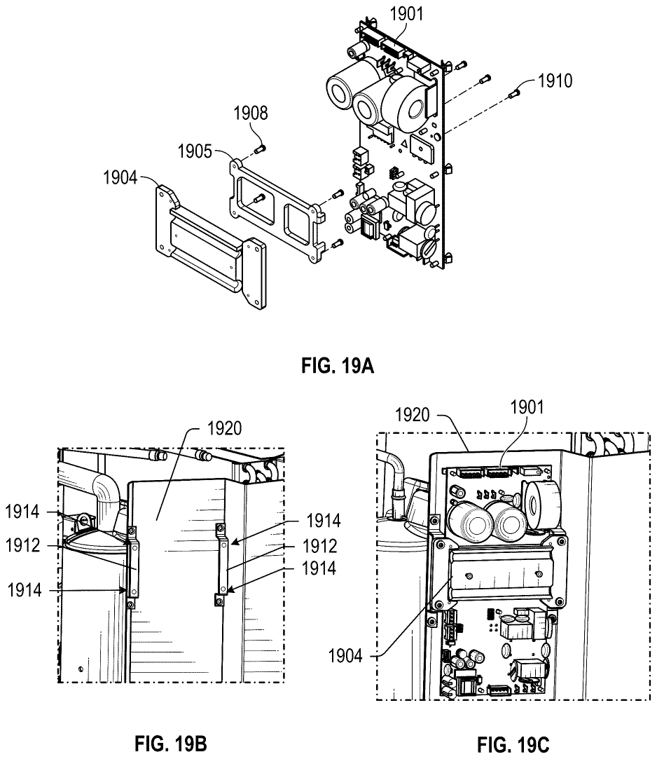

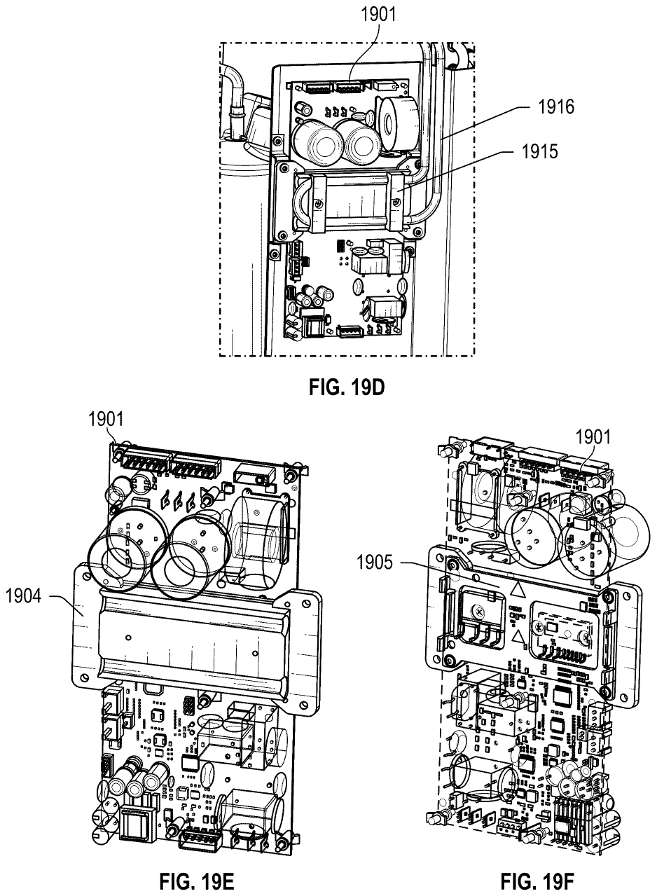

The heat sink may also be configured to be placed in contact with an electronics mounting plate on which various electronics of the heating and/or cooling appliance may be mounted. For example, a printed circuit board (PCB) including the electronics (such as a control board, for example) may be mounted to the electronics mounting plate or the individual electronics may be mounted directly to the electronics mounting plate. While reference is made herein to an electronics mounting plate, this is not intended to limit the type of structure to which the PCB including the electronic components or the electronic components themselves (and/or the heat sink) may be mounted. The PCB, electronic components, heat sink, etc. may be mounted to any type of surface on and/or within the heating and/or cooling appliance. For example, FIGS. 19B-19D show an example of an installation process in which the PCB is mounted to a chassis of a heating and/or cooling appliance, rather than to a separate mounting plate. In further embodiments, the heat sink may be mounted directly to the PCB and/or the electronics without the use of the electronics mounting plate as an interface between the two.

In this manner, the existing refrigerant loop may be leveraged to provide a cooling solution for the electronic components within the heating and/or cooling appliance. That is, the heat dissipated by the electronic components may be transferred to the fluids flowing through the refrigerant loop (such as refrigerant) via the heat sink and the refrigerant tubing that is in contact with the electronics and/or the electronics mounting plate that is in contact with the electronics.

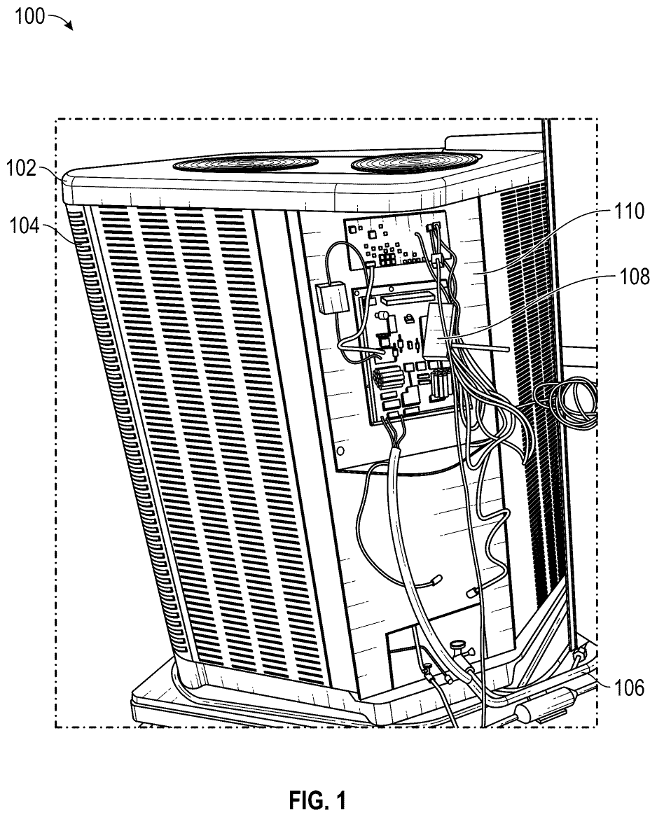

In some embodiments (as shown in FIG. 3, for example), the electronics mounting plate may also include an extrusion with an opening that is configured to receive the heat sink within the opening. That is, the opening may be sized and/or shaped such that the heat sink may be slid into the opening to form the contact between the heat sink and the electronics mounting plate. By providing this interface by which the heat sink is slid into the opening to form the contact between the heat sink and the electronics mounting plate, the heat sink and the electronics mounting plate may be more easily installed within the heating and/or cooling appliance without requiring the use of fasteners (or other types of attachment features). As illustrated in FIG. 1 below, the heat sink may be located on the back side of a PCB that is installed on the heating and/or cooling appliance and may be difficult to reach because it may require the technician to reach down into the heating and/or cooling appliance. Accordingly, the sliding action to combine the heat sink and the electronics mounting plate is easier for the technician to perform than providing fasteners through the heat sink and/or electronics mounting plate to combine the two. The same may also apply if it is desired to remove the heat sink from the electronics mounting plate or vice versa (for example, if it is desired to perform maintenance on a component).

In some embodiments, the opening in the electronics mounting plate may also be tapered such that the proximal end of the opening at which the heat sink is first inserted is larger than the distal end of the opening. The taper may be in the range of 0.25 to 2 degrees, for example, however, any other amount of taper may also be used. In some instances, all four sides of the opening may be tapered, however, in other instances only one or some of the sides may be tapered and the remaining sides may be straight.

Using a tapered opening provides several benefits. First, a mechanical feedback mechanism is provided for inserting the heat sink into the opening. Without the taper, the heat sink may be inserted any distance in the opening and it may be difficult to position the heat sink in the same location within the opening at every instance. The taper provides a point at which the heat sink may no longer be pushed into the hole and serves as a natural stopping point for inserting the heat sink into the opening. Alternatively, the opening may not pass entirely through the extrusion on the electronics mounting plate and there may be a wall of material at the distal end of the opening to provide a similar function of stopping further insertion of the heat sink.

Second, the taper may allow for the application of thermal compound on the heat sink without the thermal compound being spread unevenly over the surface of the heat sink when the heat sink is inserted into the opening. Thermal compounds (such as a thermal grease or any other type of thermal compound known in the art) are known to those of ordinary skill in the art as often being applied to one surface that is placed in contact with another surface where it is desired for thermal transfer to occur between the two surfaces. The thermal compound fills any gaps between the two surfaces to improve the thermal transfer that occurs between the two surfaces. However, if the thermal compound is provided on a surface of the heat sink and the heat sink is slid into the opening, the rubbing that occurs between the electronic mounting plate within the opening and the heat sink may cause the thermal compound to be spread along the heat sink in an undesirable manner, leading to inconsistent amounts of thermal compound along the surface of the heat sink. However, if the opening is tapered, then the opening is larger at the proximal end of the opening where the heat sink is initially inserted, resulting in less rubbing between the electronic mounting plate and the heat sink at the proximal end of the opening.

It should be noted that this embodiment by which the heat sink is slid into a portion of the electronics mounting plate is merely one example of a configuration for the heat sink and that the heat sink may also be installed in other ways as well (as another example, as indicated above, a PCB may be mounted to the chassis of the heating and/or cooling appliance and the heat sink may be mounted over the PCB into the chassis using fasteners).

Turning to the figures, FIG. 1 depicts an exemplary heating and/or cooling appliance 100. In this example, the heating and/or cooling appliance 100 is an air conditioning unit. The heating and/or cooling appliance 100 includes a base 104 and a top portion 102 that is provided on the base 104. A control board 108 is mounted to a surface 110 of the base 104. One or more electronic components may be provided on the control board 108 that are used to control various functions of the heating and/or cooling appliance 100.

The one or more electronic components included on the control board 108 may produce heat as a byproduct of operation. The one or more electronic components may have maximum recommended operating temperatures and it may be desirable to provide a mechanism by which the one or more electronic components may be cooled during the operation of the heating and/or cooling appliance 100. To perform this cooling, a heat sink (not visible in the figure) may be provided in contact with the control board 108. For example, the heat sink may be provided on a back side of the control board 108 within the interior of the heating and/or cooling appliance 100 (however, the heat sink may also be provided on contact with the front side of the control board 108 as well). Heat produced by the one or more electronic components may be dissipated through the heat sink.

To provide for even more effective heat dissipation, refrigerant tubing 106 of the heating and/or cooling appliance 100 may be routed through the heat sink or may otherwise be provided in contact with the heat sink. Accordingly, the heat may be transferred to the refrigerant that is flowing through the refrigerant tubing and may be transferred away from the control board 108. This may be existing refrigerant tubing 106 of the heating and/or cooling appliance 100 that is a part of the existing refrigerant loop (described in further detail below with respect to FIGS. 2A-2C). In some cases, additional refrigerant tubing may be added to the existing refrigerant loop to add the heat sink to the refrigerant loop.

In the specific example shown in FIG. 1, given that the heat sink may be provided in the interior of the heating and/or cooling appliance 100, the heat sink and the structure that receives the heat sink to place the heat sink in thermal contact with the control board 108 may be configured such that the heat sink may be easily slid into the structure. This provides for an easier installation process for a technician as the technician does not need to reach into the interior of the heating and/or cooling appliance to insert fasteners into the heat sink. An example of this configuration is shown in at least FIG. 3. However, it should be noted that a heat sink may be provided in other locations on other heating and/or cooling appliances and/or for different electronic components of the same heating and/or cooling appliance 100 where it may be easier for the technician to access the surface that the heat sink is mounted to. In such cases, fasteners may still be used to secure the heat sink to the surface.

As indicated above, this specific type of heating and/or cooling appliance shown in FIG. 1 is merely exemplary, and any other type of heating and/or cooling appliance including electronic components that produce heat as a byproduct may also be applicable. It should also be noted that only the exterior of the exemplary heating and/or cooling appliance 100 is shown, and the heating and/or cooling appliance may also include components located within the heating and/or cooling appliance 100 (for example, components that form a refrigerant loop as illustrated further in FIGS. 2A-2C).

FIGS. 2A-2C depict various refrigerant loops including a controller 210. That is, FIGS. 2A-2C illustrate various options for locations within the refrigerant loop that the controller 210 (including the electronic components that are desired to be cooled) may be inserted. The exemplary configurations shown in FIG. 2A-2C are merely exemplary and the controller 210 may also be provided at other locations in the refrigerant loop. Additionally, although reference is made to a “controller,” as indicated above, the refrigerant loop may also be used to cool any other types of electronic components that may be included in a heating and/or cooling appliance as well (that is, any reference herein to a controller is merely for illustrative purposes and is not intended to be limiting).

Beginning with FIG. 2A, a first exemplary refrigerant loop 200 is shown. The refrigerant loop 200 includes some or all of the elements of a conventional refrigerant loop, such as an evaporator 202, an expansion valve 204, a condenser 206, and a compressor 208. Also inserted into the refrigerant loop 200 is the controller 210 (any reference to a controller may also be replaced by any other type of electronic component that is being cooled using refrigerant from the refrigerant loop as described herein). It should be noted that the components of the refrigerant loop 200 (and the refrigerant loops 220 and 230 shown in FIGS. 2B and 2C are merely exemplary). One of ordinary skill in the art would understand that a refrigerant loop may include different components (including at least more and/or fewer components) as well. In this exemplary refrigerant loop 200, the controller 210 is inserted into the refrigerant loop 200 between the evaporator 202 and the compressor 208.

In a standard refrigerant cycle (beginning with the compressor 208), the compressor 208 receives refrigerant that is flowing through the refrigerant loop 200. The compressor 208 compresses (and thus warms) the refrigerant, and the refrigerant is then provided to the condenser 206, thus heating the condenser 206 as the warm refrigerant flows through the condenser 206. Fans may be provided that push or pull air across the condenser 206. As the air flows across the condenser 206, heat is transferred from the warm condenser 206 to the air that flows across the condenser 206. Condensed refrigerant from the condenser 206 then passes through an expansion valve 204, lowering the refrigerant's pressure and cooling the refrigerant. The refrigerant from the expansion valve 204 then passes through the evaporator 202 and returns to the compressor 208 to complete the refrigerant cycle. A fan pushes or pulls air over the evaporator 202, thereby transferring heat from the air to the refrigerant (and thus cooling the air). This cycle may be iterated any number of times to provide cooled air to a conditioned environment, such as a residential come or commercial establishment. The cooled air, for example, may be distributed to the conditioned environment via ductwork that is routed through the conditioned environment.

With the controller 210 inserted into the refrigerant loop 200 between the evaporator 202 and the compressor 208, the refrigerant that leaves the evaporator 202 may be routed through the refrigerant tubing of a heat sink (examples of various heat sink configurations are shown and described with respect to the subsequent figures) that is in thermal contact with the controller 210 before reaching the compressor 208. As the refrigerant flows through the refrigerant tubing of the heat sink, thermal transfer may occur between the controller 210 and the heat sink (and the refrigerant that is flowing through the refrigerant tubing). Thus, the refrigerant that is already flowing through the refrigerant loop 200 may be used to transfer heat dissipated by the controller 210 away from the controller 210 to cool the controller 210 during operation. The controller 210 may often operate at high temperatures that can degrade performance, shorten service life, and cause overheating, which may result in a failure of the controller 210. Accordingly, the heat sink including the refrigerant tubing serves to improve the performance of the controller 210, increase the service life of the controller 210, and prevent overheating of the controller 201, among other benefits.

Turning to FIG. 2B, a second exemplary refrigerant loop 220 is shown. The refrigerant loop 220 also includes some or all of the elements of a conventional refrigerant loop, such as an evaporator 202, an expansion valve 204, a condenser 206, and a compressor 208. In this exemplary refrigerant loop 220, the controller 210 is inserted into the refrigerant loop 220 between the expansion valve 204 and the evaporator 210. Accordingly, as the refrigerant exits the expansion valve 204, the refrigerant flows through the refrigerant tubing of the heat sink that is provided in thermal contact with the controller 210 before entering the evaporator 202. Thermal transfer then works in a similar manner as described with respect to the refrigerant loop 200 of FIG. 2A to dissipate heat from the controller 210 to the refrigerant to cool the controller 210.

Turning to FIG. 2C, a third exemplary refrigerant loop 230 is shown. The refrigerant loop 220 also includes some or all of the elements of a conventional refrigerant loop, such as an evaporator 202, an expansion valve 204, a condenser 206, and a compressor 208. In this exemplary refrigerant loop 220, the controller 210 is inserted into the refrigerant loop 220 between the condenser 206 and the expansion valve 204. Accordingly, as the refrigerant exits the condenser 206, the refrigerant flows through the refrigerant tubing of the heat sink that is provided in thermal contact with the controller 210 before entering the expansion valve 204. Thermal transfer then works in a similar manner as described with respect to the refrigerant loop 200 of FIG. 2A to dissipate heat from the controller 210 to the refrigerant to cool the controller 210.

FIG. 3 depicts an exemplary heat sink 300 for a refrigerant loop and an electronics mounting plate 306 that is configured to receive the heat sink 300. As indicated above, the electronics mounting plate 306 may be configured to receive one or more electronics of the system (for example, a heating and/or cooling appliance). Although the electronics mounting plate 306 is shown as being substantially rectangular with relatively thin side surfaces in FIG. 3, this configuration is merely exemplary and the electronics mounting plate 306 may also be configured in any other shape and/or size as well. In some embodiments, the electronics mounting plate may be made from a material that allows for effective thermal transfer, such as aluminum or copper, however, any other type of material that allows for thermal transfer may also be used.

In some embodiments, the one or more electronic components may be mounted to a first surface 307 of the electronics mounting plate 306. However, the one or more electronic components may also be mounted to a second surface 309 that is opposite to the first surface, and/or within the electronics mounting plate as well. In some embodiments, the electronics mounting plate 306 may be configured with side surfaces that are larger in size and therefore configured to receive some or all of the electronic components in addition to, or alternatively to, the first surface 307 and/or the second surface 309.

The electronics mounting plate 306 also comprises an extruding element 308 including an opening 310 for receiving the heat sink 300. That is, the electronics mounting plate 306 comprises the opening such that the heat sink 300 may be added to and removed from the electronics mounting plate 306 as desired. For example, when the electronics mounting plate 306 is installed within a system, the heat sink 300 may be slid into the opening 310 such that the heat sink 300 and electronics mounting plate 306 are then in physical contact to provide for thermal dissipation from the electronic components on and/or within the electronics mounting plate 306 to the heat sink 300. When it is desired to remove the electronics mounting plate 306 for any reason (for example, to perform maintenance on or replace any of the electronic components, then the electronics mounting plate 306 may be slid away from the heat sink 300 (or vice versa).

The opening 310 may be sized and/or shaped such that the heat sink 304 may be partially or fully slid into the opening 310 such that thermal transfer may then occur between the electronic components on and/or within the electronics mounting plate 306 and the heat sink 304 to provide thermal management for the electronic components. Although the extruding element 308 and the opening 310 are shown as being one particular size and/or shape, the extruding element 308 and opening 310 may also be any other size and/or shape (which may depend on the size and/or shape of the heat sink 300 that is used). The extruding element 308 may also be provided at any other position on the electronic mounting plate 306. In some instances, multiple of such extruding elements 308 may be provided on the electronics mounting plate 306 such that multiple heat sinks 303 may be received by the electronics mounting plate 306.

The heat sink 300 comprises a block 304 and refrigerant tubing 302. The heat sink 300 shown in FIG. 3 is one exemplary configuration of a heat sink and other variations of the heat sink are shown in subsequent figures. In this particular embodiment, the block 304 comprises apertures that are sized and/shaped to receive the refrigerant tubing 302 through the apertures. In this manner, the refrigerant tubing 302 may be routed through the block 304 while being in contact with the block 304 such that thermal transfer may occur between the block 304 and the refrigerant tubing 302 (and the fluids that flow through the refrigerant tubing 302). Although the interior of the block 304 is not visible in FIG. 3, the refrigerant tubing 302, in some embodiments, may be a singular tube 302 that is routed through the entirety of the block 304. For example, the refrigerant tubing 302 may enter the block 304 at a first end via a first aperture, route through the block 304 and exit the block at a second end, form a bend 312 outside the block 304 and route back into the block 304 via a second aperture, route through the block 304 and exit the block again at the first end. The refrigerant tubing 302 may then be routed back into the remainder of the refrigerant loop (as shown in FIGS. 2A-2C). It should be noted that FIG. 3 shows only a portion of the refrigerant tubing 302 to illustrate how the refrigerant tubing 302 is routed through the heat sink 300 and the refrigerant tubing 302 may extend back to the remainder of the refrigerant loop as well (this applies to any heat sink shown herein in any other figure as well)

This configuration is merely exemplary and the refrigerant tubing may also be routed through the block 304 in any other manner. For example, the bend 312 may be performed within the block 304 rather than outside of the block. As another example, rather than the refrigerant tubing 302 entering the block 304, bending, re-entering the block, and then exiting the block, the refrigerant tubing 302 may only flow through the block 304 in one direction such that there is only “one pass” of refrigerant tubing 302 through the block 304. The refrigerant tubing 302 may also have any other number of passes through the block 304, such as three passes, four passes, five passes, etc.

As shown in FIG. 4, the refrigerant tubing 402 (which may be the same as, or similar to, refrigerant tubing 302) may specifically be routed through the block 404 (which may be the same as, or similar to, block 304) such that the refrigerant tubing 402 aligns with the location of the electronic components on and/or within the electronics mounting plate. For example, FIG. 4 shows the locations of various exemplary electronic components 406 that may be provided. The refrigerating tubing 402 is generally aligned with the locations of the electronic components 406 to provide for maximal thermal transfer between the electronic components 406 and the refrigerant tubing 402 (and the fluids flowing through the refrigerant tubing 402). Likewise, the electronic components 406 may be positioned on and/or within the electronics mounting plate based on the manner in which the refrigerant tubing 402 is routed through the heat sink (rather than the routing of the refrigerant tubing 402 being based on the location of the electronic components 406).

Returning to FIG. 3, the opening 310 may also be tapered. The tapering may provide a number of benefits. A first benefit may include a physical stopping point for the heat sink 300 within the opening 310 at the distal end of the opening 310 when the heat sink 300 is inserted into the opening 310. A second benefit may include more easily maintaining consistent thermal compound application across the surface of the block 304 that is in contact with the electronics mounting plate 306. Thermal compounds (such as a thermal grease or any other type of thermal compound known in the art) are known to those of ordinary skill in the art as often being applied to one surface that is placed in contact with another surface where it is desired for thermal transfer to occur between the two surfaces. The thermal compound fills any gaps between the two surfaces to improve the thermal transfer that occurs between the two surfaces. However, if the thermal compound is provided on a surface of the block 304 and the heat sink 300 is slid into the opening 310, the rubbing that occurs between the electronic mounting plate within the opening 310 and the block 304 may cause the thermal compound to be spread along the block 304 in an undesirable manner, leading to inconsistent amounts of thermal compound along the surface of the block 304. However, if the opening 310 is tapered, then the opening 310 is larger at the proximal end of the opening 310 where the heat sink 300 is initially inserted, resulting in less rubbing between the electronic mounting plate 306 and the block 304 at the proximal end of the opening 310 (in turn, resulting in less undesirable spreading of the thermal compound as the heat sink 300 is inserted into the opening 310).

It should be noted that although reference may be made herein to heat sinks that are mounted to, or otherwise provided in thermal contact with, “electronics mounting plates,” these electronics mounting plates may not necessarily always be separate structures to which electronics components of a heating and/or cooling appliance are mounted. In some instances, the electronic components also be mounted to any other type of surface that may exist on and/or within a given heating and/or cooling appliance (and thus the heat sink may be mounted to, or otherwise provided in thermal contact with, any other type of surface that may exist on and/or within a given heating and/or cooling appliance). Thus, any reference to an electronics mounting plate herein is not intended to limit the type of surface to which the heat sink and/or electronic components being cooled using the heat sink may be mounted or otherwise provided with in thermal contact. For example, the extruding element 308 may also be provided on an existing surface of a heating and/or cooling appliance, such as the chassis of the heating and/or cooling appliance. As another example (shown in FIGS. 19B-19D), a PCB and/or heat sink may be mounted to the chassis of a heating and/or cooling appliance. These are merely examples and any other surface may also be used.

FIGS. 5-6 depict additional exemplary heat sinks for a refrigerant loop. Beginning with FIG. 5, Another heat sink 500 is shown that comprises a plate 504 rather than a solid block that receives the refrigerant tubing 502 within an interior of the block. In this exemplary configuration, the refrigerant tubing 502 may be routed along one side of the plate 504 and the electronic components 506 may be provided on an opposite surface of the plate 504 such that thermal transfer may occur between the electronic components 506 and the refrigerant tubing 502 (and the fluids that flow through the refrigerant tubing). This configuration also illustrates that, in some embodiments, the separate electronics mounting plate may not necessarily be required and the electronic components 506 may also be mounted directly to the heat sink. However, there may still be an interface between an electronic component 506 and the plate 504.

Turning to FIG. 6, another exemplary heat sink 600 is shown in which the refrigerant tubing is not routed through the entire block 610. In this exemplary configuration, the refrigerant tubing 602 is routed to the location of the block 610 and ends at the location of the block 610, rather than routing through the block 610 itself. In the example shown in FIG. 6, the refrigerant tubing 602 is routed up to block tubing 604 that extrudes from the block 610 itself. The refrigerant tubing 602 may be connected to the block tubing 604 through any suitable manner, such as welding, etc. the fluids that flow through the refrigerant tubing 602 may then flow through the block 610 itself and return back to the refrigerant tubing 602 to return to the refrigerant loop rather than flowing through the block 610 through the refrigerant tubing 602 itself. For example, the interior of the block 610 may include apertures that are machined into the block 610 to allow the fluids to flow through the block 610. The block 610 may also include an integrated bend 612, however, this bend 612 is not necessarily required. In some embodiments, rather than apertures being machined into the interior of the block 610, the entirety of the block 610 may be a cavity such that the fluids may spread around the entirety of the interior of the block 610 to provide more direct thermal transfer across a larger surface area of the block 610. This cavity may also not necessarily be formed as the entirety of the interior of the block 610 but rather may only be a portion of the interior of the block 610 in some embodiments as well. For example, the cavity may be machined within the block 610 at the locations where the electronic components are more likely to be in contact with the block 610.

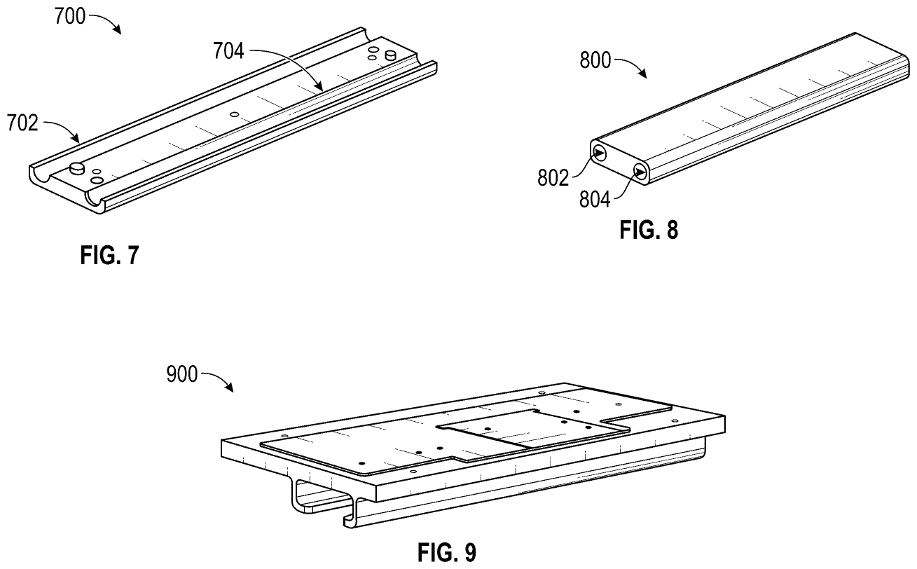

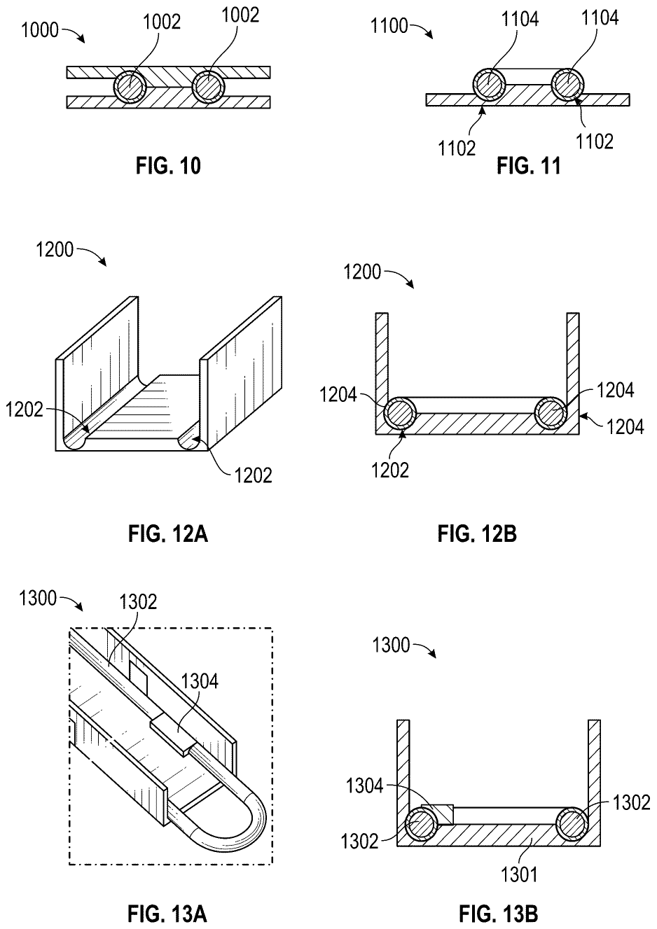

FIGS. 7-8 depict additional exemplary heat sinks without refrigerant tubing. Specifically, FIGS. 7-8 illustrate two exemplary configurations of heat sinks that are both configured to receive refrigerant tubing (not shown in FIGS. 7-8). In the first configuration, the heat sink 700 includes grooves 704 and 704 that are configured to receive the refrigerant tubing (not shown in the figure). In contrast, FIG. 8 shows another configuration in which a heat sink 800 includes openings 802 and 804 that are configured to receive the refrigerant tubing (not shown in the figure). FIGS. 7-8 illustrate that a heat sink may, in some configurations, fully encompass the refrigerant tubing that is routed through the heat sink, and, in other configurations, may only receive and be in contact with the refrigerant tubing, but may not necessarily fully encompass the refrigerant tubing. FIGS. 10-11 depict cross-section views of additional heat sinks with refrigerant tubing. Specifically, FIG. 10 shows a heat sink 1000 that encompasses the refrigerant tubing 1002, similar to the heat sink 800 of FIG. 8 and FIG. 11 shows a heat sink 1100 that includes grooves 1102 for receiving the refrigerant tubing 1104, similar to the heat sink 700 of FIG. 7. FIG. 9 depicts another electronics mounting plate 900 that receives a heat sink.

FIG. 12A depicts a perspective view of another heat sink 1200 without refrigerant tubing. Specifically, the heat sink 1200 is shown as including one or more grooves 1202. The one or more grooves 1202 may be configured to receive refrigerant tubing within the one or more grooves 1202. By including the grooves 1202 for receiving the refrigerant tubing rather than the refrigerant tubing contacting a flat surface of the heat sink 1200, additional contact is provided between the surface of the refrigerant tubing and the surface of the heat sink 1200 (resulting in improved thermal transfer between the heat sink 1200 and the refrigerant tubing). The heat sink 1200 is shown as being a plate (similar to the plate 504 of FIG. 5), however, the same grooves may also be provided in a block as well. FIG. 12B depicts a cross-section view of the heat sink 1200 of FIG. 12A including the refrigerant tubing 1206 provided within the grooves 1204.

FIG. 13A depicts a perspective view of another heat sink 1300 that includes a further modification to the heat sink 1200 of FIGS. 12A-12B. Specifically, the heat sink 1300, similar to the heat sink 1200, includes one or more grooves for receiving the refrigerant tubing 1302. The heat sink 1300, however, also includes additional structure 1304 provided on top of the refrigerant tubing 1302 to provide even further contact between the surface of the refrigerant tubing 1302 and the material that forms the heat sink 1300. FIG. 13B depicts a cross-section view of the heat sink 1300 of FIG. 13A showing the contact between the refrigerant tubing 1302 and the grooves 1304 and the additional contact between the refrigerant tubing 1302 and the additional structure 1304.

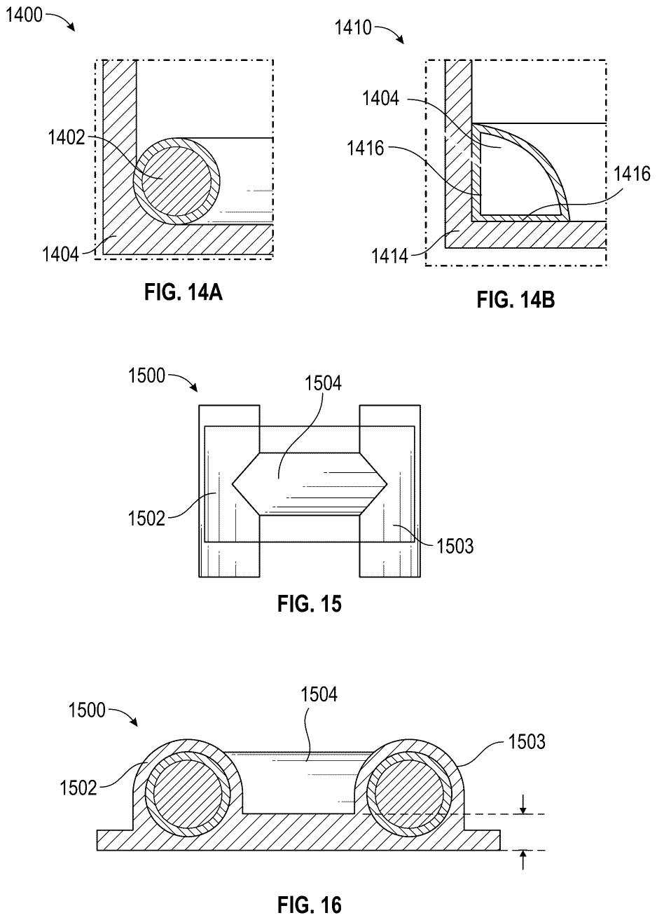

FIGS. 14A-14B depict cross-section views of different types of refrigerant tubing. Specifically, FIG. 14A shows a heat sink 1400 that includes refrigerant tubing 1402 that is rounded. The plate 1404 (or block) that forms the heat sink that the refrigerant tubing 1402 is in contact with may also be rounded (as shown in FIGS. 12A-13B) such that there is maximum contact between the refrigerant tubing 1402 and the plate 1404 (or block) to provide for maximum thermal transfer. FIG. 14B shows another configuration of refrigerant tubing 1412 for another heat sink 1410. In this exemplary configuration, the refrigerant tubing includes one or more flat surfaces 1416 rather than being completely rounded. The configuration of refrigerant tubing 1412 with the flat surfaces 1416 also provides for improved contact between the refrigerant tubing 1412 and the plate 1414 (or block) of the heat sinks 1400 and 1410. For example, if the grooves are not included in the plate 141 (or block), then the refrigerant tubing 1412 may be provided with the flat surfaces 1416 to increase the contact between the refrigerant tubing 1412 and the plate 1414 (or block) in a similar manner that the grooves provide for increased contact with the surface of rounded refrigerant tubing. This concept may be extended to any other shape of plate (or block) and refrigerant tubing.

FIG. 15 depicts a top-down view of a portion of yet further refrigerant tubing 1500. FIG. 16 depicts a cross-section view of the refrigerant tubing 1500. Particularly, FIGS. 15-16 illustrate that the refrigerant tubing 1500 does not necessarily need to only run straight through the length of the heat sink from one end of the heat sink to another end of the heat sink. Rather, the refrigerant tubing 1500 may be routed through the heat sink in any number of different configurations. In the example shown in FIGS. 15-16, the refrigerant tubing 1500 includes a bridge 1502 between a first portion 1502 of the refrigerant tubing 1500 and a second portion 1503 of the refrigerant tubing 1500. The bridge 1504 allows the refrigerant to not only flow up the first portion 1502, around the bend in the refrigerant tubing (as illustrated in FIG. 3, for example), and back through the second portion 1504, the refrigerant may also flow between the first portion 1502 and the second portion 1504 via the bridge 1504. This may be beneficial for a number of reasons. For example, there may be an electronic component at the location of the bridge 1504 and providing the bridge 1504 at that specific location may provide for more effective thermal transfer between that electronic component and the refrigerant flowing through the refrigerant tubing 1500.

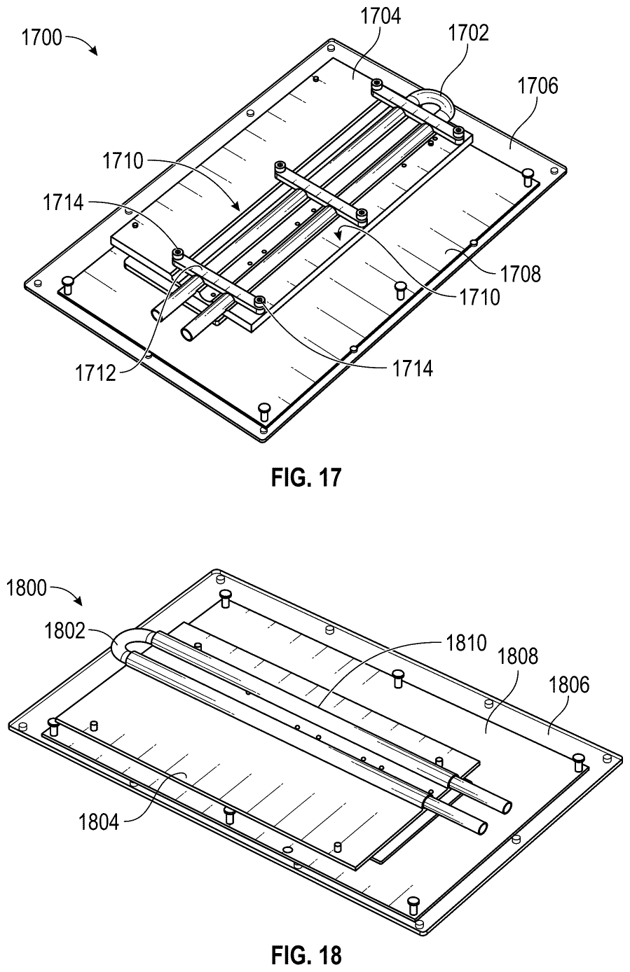

FIG. 17-18 depicts yet further exemplary heat sinks for a refrigerant loop mounted on an electronics mounting plate. FIGS. 17-18 show configurations in which the heat sink is mounted to the electronics mounting plate in a manner other than sliding the heat sink into the electronics mounting plate. FIGS. 17-18 also show yet further heat sink configurations.

Beginning with FIG. 17, a heat sink 1700 is shown as being mounted to an electronics mounting plate 1706 on a first surface of the electronics mounting plate 1706. A PCB 1708 is shown as being mounted to a second surface of the electronics mounting plate 1706 that is opposite to the first surface (the electronics mounting plate 1706 is partially transparent in FIGS. 17-18 such that the PCB 1708 is visible behind the electronics mounting plate 1706). The heat sink 1700 and electronics mounting plate 1706 may be made from materials that allow for thermal transfer from the electronic components on the PCB 1708, through the electronics mounting plate 1706, and to the heat sink 1700 such that the electronic components on the PCB 1708 may be cooled by the heat sink 1700. In some instances, the electronics mounting plate 1706 may not necessarily be a separate component but may also be any surface of a heating and/or cooling appliance in which the PCB 1708 and the heat sink 1700 are provided. For example, as shown in FIG. 1, the PCB 1708 may be mounted to an exterior surface of the heating and/or cooling appliance (or any other surface).

More specifically, refrigerant tubing 1702 may be routed along the heat sink 1700. In the configuration shown in FIG. 17, the refrigerant tubing 1702 may be routed through grooves 1710 provided in the heat sink 1700 such that there is enhanced contact between the refrigerant tubing 1702 and the surface of the heat sink 1700. To hold the refrigerant tubing 1702 within the grooves 1710, one or more brackets 1712 may be provided over the refrigerant tubing 1702 at the location of the grooves 1710. The one or more brackets 1712 may be secured to the heat sink 1700 using fasteners (for example, fasteners 1714), such as bolts, screws, and/or any other type of fastener. In the example shown in FIG. 17, one fastener 1714 is provided on one end of the bracket 1712 and one fastener 1714 is provided on another end of the bracket 1712. However, the brackets may also be secured to the heat sink 1700 (or any other element shown in FIG. 17) in using any other suitable mechanism. Additionally, the use of the brackets 1712 to secure the refrigerant tubing 1702 within the grooves 1710 is merely exemplary and the refrigerant tubing 1702 may be secured in the grooves in any other suitable manner.

Although the refrigerant tubing 1702 is shown as being routed from a first end of the heat sink 1700, to a second end of the heat sink 1700, around a bend, back into the second end of the heat sink 1700, and back out of the first end of the heat sink 1700, this is merely one manner in which the refrigerant tubing 1702 may be routed through the heat sink 1700. The refrigerant tubing 1702 may also be routed through the heat sink 1700 in any other manner, including any other number of passes through the heat sink (one, three, four, five, etc.). The refrigerant tubing 1702 may also include bridges between the lengths of the refrigerant tubing (as shown in FIGS. 15-16). The refrigerant tubing 1702 may also be sized and/or shaped and/or routed in any other manner.

Turning to FIG. 18, similar components as FIG. 17 are shown (for example, the heat sink 1800 may be the same as, or similar to, heat sink 1700, electronics mounting plate 1806 may be the same as, or similar to, electronics mounting plate 1706, PCB 1806 may be the same as PCB 1706, etc.). Similar to the heat sink 1700 in FIG. 17, the heat sink 1800 in FIG. 18 is shown as being mounted to an electronics mounting plate 1706 on a first surface of the electronics mounting plate 1706. The PCB 1808 is shown as being mounted to a second surface of the electronics mounting plate 1806 which is opposite to the first surface. Again, the electronics mounting plate 1706 may not necessarily be a separate component but may also be any surface of a heating and/or cooling appliance in which the PCB 1708 and the heat sink 1700 are provided. For example, as shown in FIG. 1, the PCB 1708 may be mounted to an exterior surface of the heating and/or cooling appliance (or any other surface).

In contrast with the heat sink 1700 shown in FIG. 18, the heat sink 1800 shown in FIG. 18 includes cavities 1810 configured to receive the refrigerant tubing 1802 rather than the refrigerant tubing 1802 being routed through grooves 1710 in the heat sink and being held within the grooves using brackets 1712 or other types of mechanisms. Accordingly, the heat sink 1800 fully encompasses the portion of the refrigerant tubing 1802 that is in contact with the heat sink 1800.

FIG. 19A depicts an exploded view of an assembly for mounting a heat sink 1940 and a PCB 1901 to a surface of a heating and/or cooling appliance (shown in FIGS. 19B-19D). FIGS. 19A-19F show another configuration in which the heat sink is mounted to the PCB 1901 and/or a surface of a heating and/or cooling appliance using fasteners, in contrast with the configuration shown in FIG. 3 in which the heat sink is slid into an opening. In some embodiments, the assembly 1902 may include the heat sink 1902 and a spacer 1905. The spacer 1905 may be provided between the heat sink 1904 and the PCB 1901 when the heat sink 1902 is mounted over the PCB 1901. The spacer 1905 provides clearance between the heat sink 1904 and the PCB 1901 for the electrical components on the PCB 1901 that are in contact with the heat sink 1904. FIG. 19E shows the heat sink 1904 mounted to the PCB 1901 and FIG. 19F shows the heat sink 1904 as transparent such that the spacer 1905 is visible underneath the heat sink 1904.

FIG. 19B-19D depict an exemplary installation process for a printed circuit board 1902 and a heat sink 1904 onto a surface 1920 of an exemplary heating and/or cooling appliance. The installation process may be performed to limit the strain on the PCB 1901 and the electronic components included on the PCB 1901. To limit this strain, the PCB 1901 may be fastened to the heat sink 904 and then the heat sink 1904 may be fastened into the surface 1920 of the heating and/or cooling appliance.

Specifically, during the installation process, one or more brackets 1912 may be fastened to the surface 1920 to which the PCB 1901 and/or heat sink 1904 are to be mounted. The one or more brackets 1912 may include fastener apertures 1914 configured to receive fasteners that may be used to secure the heat sink 1904 to the one or more brackets 1914. Accordingly, one the heat sink assembly 1902 is mounted to the PCB 1901, the PCB 1901 may then be mounted to the one or more brackets 1912 via fasteners provided through fastener apertures on the heat sink 1904 and the fastener apertures 1914 provided on the one or more brackets 1912. Finally, FIG. 19D shows the refrigerant tubing 1916 is routed such that the refrigerant tubing 1916 is in contact with the heat sink 1902. In the particular example shown in FIG. 19D, the refrigerant tubing 1914 is secured in contact with the heat sink 1904 using one or more brackets 1914 (in a similar manner shown in FIG. 17).

It should be noted that the installation process illustrated in FIGS. 19B-19D is applicable to configurations in which a heat sink and the printed circuit board that includes the electronic components being cooled by the heat sink are fastened to the heating and/or cooling appliance. However, as described elsewhere herein, in some embodiments, the electronics mounting plate (or other surface on and/or within the heating and/or cooling appliance) to which the PCB is mounted may be configured such that the heat sink may instead be slid into and out of the electronics mounting plate (or other surface).

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

We claim:

1. A heating, ventilation, and air conditioning (HVAC) unit comprising:
one or more electrical components; and
a heat sink for dissipating heat produced by the one or more electrical components, wherein the heat sink is in contact with refrigerant tubing of the HVAC unit, and wherein the heat sink is configured to cause thermal transfer between the one or more electrical components and fluid within the refrigerant tubing.

2. The HVAC unit of claim 1, further comprising a plate configured to receive the one or more electrical components, wherein the plate further comprises an opening configured to slidably receive the heat sink.

3. The HVAC unit of claim 2, wherein the opening is tapered with a proximal end of the opening that is larger than a distal end of the opening.

4. The HVAC unit of claim 1, wherein the heat sink further comprises one or more openings such that the heat sink is configured to receive the refrigerant tubing within the heat sink.

5. The HVAC unit of claim 4, wherein the heat sink further comprises a first opening and a second opening, wherein the first opening is configured to receive a first portion of the refrigerant tubing and the second opening is configured to receive a second portion of the refrigerant tubing, wherein the fluid flows in a first direction through the first portion and a second direction through the second portion.

6. The HVAC unit of claim 1, wherein the heat sink is positioned within a refrigerant loop of the HVAC unit such that the fluid flows from an evaporator of the HVAC unit, into the heat sink, and into a compressor of the HVAC unit.

7. The HVAC unit of claim 1, wherein the heat sink is positioned within a refrigerant loop of the HVAC unit such that the fluid flows from an expansion valve of the HVAC unit, into the heat sink, and into an evaporator of the HVAC unit.

8. The HVAC unit of claim 1, wherein the heat sink is positioned within a refrigerant loop of the HVAC unit such that the fluid flows from a condenser of the HVAC unit, into the heat sink, and into an expansion valve of the HVAC unit.

9. A heat sink for one or more electrical components of a heating, ventilation, and air conditioning (HVAC) unit, the heat sink comprising:
refrigerant tubing that is in fluid communication with a refrigerant loop of the HVAC unit, wherein the heat sink is configured to dissipate heat produced by the one or more electrical components by causing thermal transfer between the one or more electrical components and fluid within the refrigerant tubing.

10. The heat sink of claim 9, wherein the heat sink is configured to be slid into an opening in a plate configured to receive the one or more electrical components.

11. The heat sink of claim 9, wherein the heat sink further comprises one or more openings such that the heat sink is configured to receive the refrigerant tubing within the heat sink.

12. The heat sink of claim 11, wherein the heat sink further comprises a first opening and a second opening, wherein the first opening is configured to receive a first portion of the refrigerant tubing and the second opening is configured to receive a second portion of the refrigerant tubing, wherein the fluid flows in a first direction through the first portion and a second direction through the second portion.

13. The heat sink of claim 9, wherein the heat sink is positioned within a refrigerant loop of the HVAC unit such that the fluid flows from an evaporator of the HVAC unit, into the heat sink, and into a compressor of the HVAC unit.

14. The heat sink of claim 9, wherein the heat sink is positioned within a refrigerant loop of the HVAC unit such that the fluid flows from an expansion valve of the HVAC unit, into the heat sink, and into an evaporator of the HVAC unit.

15. The heat sink of claim 9, wherein the heat sink is positioned within a refrigerant loop of the HVAC unit such that the fluid flows from a condenser of the HVAC unit, into the heat sink, and into an expansion valve of the HVAC unit.

16. A system comprising:
one or more electrical components; and
a heat sink for dissipating heat produced by the one or more electrical components, wherein the heat sink is in contact with refrigerant tubing, and wherein the heat sink is configured to cause thermal transfer between the one or more electrical components and fluid within the refrigerant tubing.

17. The system of claim 16, further comprising a plate configured to receive the one or more electrical components, wherein the plate further comprises an opening configured to slidably receive the heat sink.

18. The system of claim 17, wherein the opening is tapered with a proximal end of the opening that is larger than a distal end of the opening.

19. The system of claim 16, wherein the heat sink further comprises one or more openings such that the heat sink is configured to receive the refrigerant tubing within the heat sink.

20. The system of claim 19, wherein the heat sink further comprises a first opening and a second opening, wherein the first opening is configured to receive a first portion of the refrigerant tubing and the second opening is configured to receive a second portion of the refrigerant tubing, wherein the fluid flows in a first direction through the first portion and a second direction through the second portion.
